(19) United States
(12) Patent Application Publication
(10) Pub. No.: US 2010/0212730 A1
(43) Pub. Date: Aug. 26, 2010

(54) PHOTOVOLTAIC DEVICES INCLUDING BACK METAL CONTACTS

(75) Inventor: Igor Sankin, Perrysburg, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/641,308

(22) Filed: Dec. 17, 2009

Related U.S. Application Data
(60) Provisional application No. 61/138,914, filed on Dec. 18, 2008.

(51) Int. Cl. H01L 31/0296; H01L 31/00; H01L 31/18

(52) U.S. Cl. 136/255; 136/256; 438/84; 257/E31.015

(57) ABSTRACT

A photovoltaic cell can include a substrate having a transparent conductive oxide layer, a CdS/CdTe layer, and a back metal contact. The back metal contact can be deposited by sputtering or by chemical vapor deposition.

### CLAIM OF PRIORITY

This application claims priority to U.S. Provisional Patent Application No. 61/138,914, filed on Dec. 18, 2008, which is incorporated by reference in its entirety.

### TECHNICAL FIELD

This invention relates to photovoltaic devices and back metal contacts.

### BACKGROUND

During the fabrication of photovoltaic devices, layers of semiconductor material can be applied to a substrate with one layer serving as a window layer and a second layer serving as the absorber layer. Some photovoltaic devices are relatively inefficient at converting solar energy to electrical power.

### DESCRIPTION OF DRAWINGS

FIG. 1 is a schematic of a photovoltaic device having multiple layers.

FIG. 2 is a schematic of the energy band gaps of the layers in a photovoltaic device.

### DETAILED DESCRIPTION

A photovoltaic cell can include one or more layers of material adjacent to a substrate. A layer can include one or more layers or films. A layer can include any any amount of any material that contacts all or a portion of a surface. A photovoltaic cell can include a transparent conductive layer on a surface of the substrate, a semiconductor layer, and a back metal layer in contact with the semiconductor layer. The window layer can allow the penetration of solar radiation to the absorber layer, where the optical power is converted into electrical power. Some photovoltaic devices can use transparent thin films that are also conductors of electrical charge. The conductive thin films can include transparent conductive layers that contain a transparent conductive oxide (TCO), such as a tin oxide. The TCO can allow light to pass through a semiconductor window layer to the active light absorbing material and also serve as an ohmic contact to transport photogenerated charge carriers away from the light absorbing material. A back electrode can be formed on the back surface of a semiconductor layer. The back electrode can include electrically conductive material.

In general, a photovoltaic device can include a first semiconductor layer which can be positioned over a transparent conductive layer. A photovoltaic device can include a second semiconductor layer, which can be positioned over the first semiconductor layer. A photovoltaic device can include a poly-silicon back metal contact. The poly-silicon back metal contact can be a p-type doped poly-silicon. The p-type doped poly-silicon can have a carrier concentration of at least 1×10¹⁷ cm⁻³. The poly-silicon back metal contact can be a degenerate p-type doped poly-silicon with a carrier concentration of at least 5×10¹⁹ cm⁻³. The first semiconductor layer can include cadmium sulfide. The second semiconductor layer can include cadmium telluride.

A photovoltaic device can include a first semiconductor layer, which can be positioned over a transparent conductive layer. The photovoltaic device can include a second semiconductor layer, which can be positioned over the first semiconductor layer. The photovoltaic device can include an amorphous-silicon back metal contact, which can be adjacent to the second semiconductor layer. The amorphous-silicon back metal contact can include a boron dopant. The first semiconductor layer can include cadmium sulfide. The second semiconductor layer can include cadmium telluride.

In one aspect, a method of manufacturing a photovoltaic device can include depositing a first semiconductor layer, which can include a cadmium sulfide semiconductor. The method can include depositing a second semiconductor layer on the first semiconductor layer, which can include a cadmium telluride semiconductor. The method can include depositing a back metal contact, which can include a poly-silicon. The poly-silicon back metal contact can be a p-type doped poly-silicon. The back metal contact can be deposited by chemical vapor deposition. The back metal contact can be deposited by low pressure chemical vapor deposition. The back metal contact can be deposited by plasma enhanced chemical vapor deposition. The back metal contact can be deposited by sputtering.

In one aspect, a method of manufacturing a photovoltaic device can include depositing a first semiconductor layer, which can include a cadmium sulfide semiconductor. The method can include depositing a second semiconductor layer on the first semiconductor layer, which can include a cadmium telluride semiconductor. The method can include depositing a back metal contact, which can include an amorphous-silicon. The amorphous-silicon back metal contact can include a boron dopant. The back metal contact can be deposited by chemical vapor deposition. The back metal contact can be deposited by low pressure chemical vapor deposition. The back metal contact can be deposited by plasma enhanced chemical vapor deposition. The back metal contact can be deposited by sputtering.

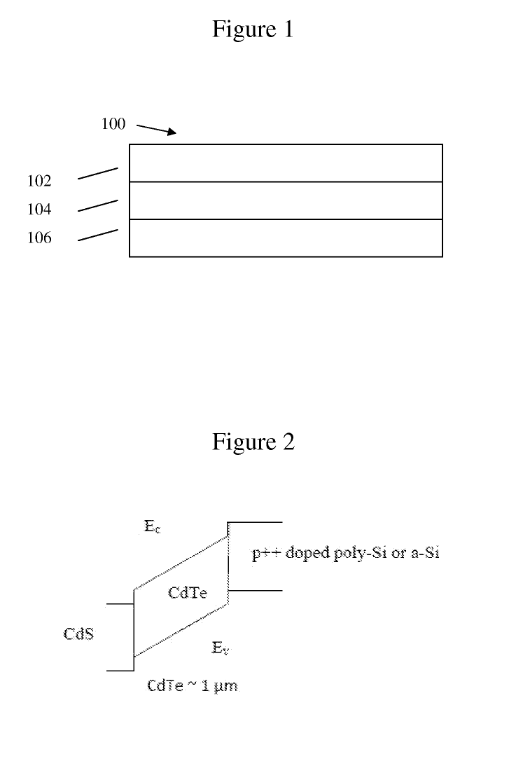

Referring to FIG. 1, a photovoltaic cell 100 can include a first semiconductor layer 102. The first semiconductor layer 102 can be cadmium sulfide, for example. The photovoltaic cell 100 can include a second semiconductor layer 104. The second semiconductor layer 104 can be cadmium telluride, for example. The photovoltaic cell 100 can include a back metal contact 106 on the second semiconductor layer 104. The back metal contact 106 can be amorphous silicon or polycrystalline silicon. An optional diffusion barrier (not shown) can be added between the second semiconductor layer 104 and the back metal contact 106. The back metal contact 106 can be deposited via low pressure chemical vapor deposition, plasma-enhanced chemical vapor deposition, or sputtering, for example.

Amorphous silicon cells may include polycrystalline silicon based solar cells that have a silicon nitride gate dielectric/amorphous silicon semiconductor interface. See for example U.S. Pat. No. 5,273,920, U.S. Pat. No. 5,281,546, M. J. Keeves, A. Turner, U. Schubert, P. A. Basore, M. A. Green, 20^{th} EU Photovoltaic Solar Energy Conf., Barcelona (2005) p 1305-1308; P. A. Basore, 4^{th} World Conf. Photovoltaic Energy Conversion, Hawaii (2006) p 2089-2093, which are incorporated by reference herein.

A difference between polycrystalline silicon, or poly-silicon (also known as poly-Si or poly), and amorphous silicon (also known as a-Si) is that the mobility of the charge carriers can be orders of magnitude larger for poly-Si and the material also shows greater stability under electric field and light-induced stress. Another difference is that a-Si has better low-leakage characteristics.

The back metal contact 106 can be degenerately doped p-type a-Si or micro-crystalline silicon. In order to provide efficient charge separation in the CdTe absorber layer 104, the back metal contact 106 can be p++ a-Si or poly-Si. The poly-Si can be p-type doped with a carrier concentration of at least 1×10¹⁷ cm⁻³. The poly-Si can be degenerate p-type doped with a carrier concentration of at least 5×10¹⁹ cm⁻³. The a-Si can use a boron dopant.

Referring to FIG. 2, the energy bandgaps of CdS, CdTe, and amorphous silicon or polysilicon are shown. The bandgap determines what portion of the solar spectrum a photovoltaic cell absorbs. Typically, a wider bandgap is preferred to a narrow one, because a wider portion of the solar spectrum is available to be converted to energy. In FIG. 2, with a layer of CdTe of approximately 1 μm, the increase in energy bandgap between CdS and CdTe and between CdTe and poly-Si or a-Si is shown. The addition of poly-Si or a-Si is chosen because it appears to increase the bandgap.

A common photovoltaic cell can have multiple layers. The multiple layers can include a bottom layer that is a transparent conductive layer, a capping layer, a window layer, an absorber layer and a top layer. Each layer can be deposited at a different deposition station of a manufacturing line with a separate deposition gas supply and a vacuum-sealed deposition chamber at each station as required. The substrate can be transferred from deposition station to deposition station via a rolling conveyor until all of the desired layers are deposited. A top substrate layer can be placed on top of the top layer to form a sandwich and complete the photovoltaic cell.

Deposition of semiconductor layers in the manufacture of photovoltaic devices is described, for example, in U.S. Pat. Nos. 5,248,349, 5,372,646, 5,470,397, 5,536,333, 5,945,163, 6,037,241, and 6,444,043, each of which is incorporated by reference in its entirety. The deposition can involve transport of vapor from a source to a substrate, or sublimation of a solid in a closed system. An apparatus for manufacturing photovoltaic cells can include a conveyor, for example a roll conveyor with rollers. Other types of conveyors are possible. The conveyor transports substrate into a series of one or more deposition stations for depositing layers of material on the exposed surface of the substrate. Conveyors are described in provisional U.S. application Ser. No. 11/692,667, which is hereby incorporated by reference.

The deposition chamber can be heated to reach a processing temperature of not less than about 450° C. and not more than about 700° C., for example the temperature can range from 450-550° C., 550-650° C., 570-600° C., 600-640° C. or any other range greater than 450° C. and less than about 700° C. The deposition chamber includes a deposition distributor connected to a deposition vapor supply. The distributor can be connected to multiple vapor supplies for deposition of various layers or the substrate can be moved through multiple and various deposition stations with its own vapor distributor and supply. The distributor can be in the form of a spray nozzle with varying nozzle geometries to facilitate uniform distribution of the vapor supply.

The window layer and the absorbing layer can include, for example, a binary semiconductor such as group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, MN, AlP, AlAs, AlSb, GaN, GaP, GaAs, GaSb, InN, InP, InAs, InSb, TlN, TlP, TlAs, TlSb, or mixtures thereof. An example of a window layer and absorbing layer is a layer of CdS coated by a layer of CdTe. A top layer can cover the semiconductor layers. The top layer can include a metal such as, for example, aluminum, molybdenum, chromium, cobalt, nickel, titanium, tungsten, or alloys thereof. The top layer can also include metal oxides or metal nitrides or alloys thereof.

The bottom layer of a photovoltaic cell can be a transparent conductive layer. A thin capping layer can be on top of and at least covering the transparent conductive layer in part. The next layer deposited is the first semiconductor layer, which can serve as a window layer and can be thinner based on the use of a transparent conductive layer and the capping layer. The next layer deposited is the second semiconductor layer, which serves as the absorber layer. Other layers, such as layers including dopants, can be deposited or otherwise placed on the substrate throughout the manufacturing process as needed.

The transparent conductive layer can be a transparent conductive oxide, such as a metallic oxide like tin oxide, which can be doped with, for example, fluorine. This layer can be deposited between the front contact and the first semiconductor layer, and can have a resistivity sufficiently high to reduce the effects of pinholes in the first semiconductor layer. Pinholes in the first semiconductor layer can result in shunt formation between the second semiconductor layer and the first contact resulting in a drain on the local field surrounding the pinhole. A small increase in the resistance of this pathway can dramatically reduce the area affected by the shunt.

A capping layer can be provided to supply this increase in resistance. The capping layer can be a very thin layer of a material with high chemical stability. The capping layer can have higher transparency than a comparable thickness of semiconductor material having the same thickness. Examples of materials that are suitable for use as a capping layer include silicon dioxide, dialuminum trioxide, titanium dioxide, diboron trioxide and other similar entities. Capping layer can also serve to isolate the transparent conductive layer electrically and chemically from the first semiconductor layer preventing reactions that occur at high temperature that can negatively impact performance and stability. The capping layer can also provide a conductive surface that can be more suitable for accepting deposition of the first semiconductor layer. For example, the capping layer can provide a surface with decreased surface roughness.

The first semiconductor layer can serve as a window layer for the second semiconductor layer. The first semiconductor layer can be thinner than the second semiconductor layer. By being thinner, the first semiconductor layer can allow greater penetration of the shorter wavelengths of the incident light to the second semiconductor layer.

The first semiconductor layer can be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AlN, AlP, AlAs, AlSb, GaN, GaP, GaAs, GaSb, InN, InP, InAs, InSb, TlN, TlP, TlAs, TlSb, or mixtures or alloys thereof. It can be a binary semiconductor, for example it can be CdS. The second semiconductor layer can be deposited onto the first semiconductor layer. The second semiconductor can serve as an absorber layer for the incident light when the first semiconductor layer is serving as a window layer. Similar to the first semiconductor layer, the second semiconductor layer can also be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AlN, AlP, AlAs, AlSb, GaN, GaP, GaAs, GaSb, InN, InP, InAs, InSb, TlN, TlP, TlAs, TlSb, or mixtures thereof.

The second semiconductor layer can be deposited onto a first semiconductor layer. A capping layer can serve to isolate a transparent conductive layer electrically and chemically from the first semiconductor layer preventing reactions that occur at high temperature that can negatively impact performance and stability. The transparent conductive layer can be deposited over a substrate.

A number of embodiments have been described. Nevertheless, it will be understood that various modifications may be made without departing from the spirit and scope of the invention. For example, the semiconductor layers can include a variety of other materials, as can the materials used for the buffer layer and the capping layer. In addition, the device may contain interfacial layers between a second semiconductor layer and a back metal electrode to reduce resistive losses and recombination losses at the interface between the second semiconductor and the back metal electrode. Accordingly, other embodiments are within the scope of the following claims.

What is claimed is:

1. A photovoltaic device comprising:
a first semiconductor layer, the first semiconductor layer positioned over a transparent conductive layer;
a second semiconductor layer, the second semiconductor layer positioned over the first semiconductor layer; and
a poly-silicon back metal contact.

2. The photovoltaic device of claim 1, wherein the poly-silicon back metal contact is a p-type doped poly-silicon.

3. The photovoltaic device of claim 1, wherein the poly-silicon back metal contact is a p-type doped poly-silicon with a carrier concentration of at least 1×10¹⁷ cm⁻³.

4. The photovoltaic device of claim 1, wherein the poly-silicon back metal contact is a degenerate p-type doped poly-silicon with a carrier concentration of at least 5×10¹⁹ cm⁻³.

5. The photovoltaic device of claim 1, wherein the first semiconductor layer is a cadmium sulfide.

6. The photovoltaic device of claim 1, wherein the first semiconductor layer includes cadmium sulfide.

7. The photovoltaic device of claim 1, wherein the second semiconductor layer is a cadmium telluride.

8. The photovoltaic device of claim 1, wherein the second semiconductor layer includes cadmium telluride.

9. A photovoltaic device comprising:
a first semiconductor layer, the first semiconductor layer positioned over a transparent conductive layer;
a second semiconductor layer, the second semiconductor layer positioned over the first semiconductor layer; and
an amorphous-silicon back metal contact.

10. The photovoltaic device of claim 9, wherein the amorphous-silicon back metal contact includes a boron dopant.

11. The photovoltaic device of claim 9, wherein the first semiconductor layer is a cadmium sulfide.

12. The photovoltaic device of claim 9, wherein the first semiconductor layer includes cadmium sulfide.

13. The photovoltaic device of claim 9, wherein the second semiconductor layer is a cadmium telluride.

14. The photovoltaic device of claim 9, wherein the second semiconductor layer includes cadmium telluride.

15. A method of manufacturing a photovoltaic device comprising:
depositing a first semiconductor layer, the first semiconductor layer including a cadmium sulfide semiconductor;
depositing a second semiconductor layer on the first semiconductor layer, the second semiconductor layer including a cadmium telluride semiconductor; and
depositing a back metal contact, the back metal contact including a poly-silicon.

16. The method of claim 15, wherein the back metal contact is deposited by low pressure chemical vapor deposition.

17. The method of claim 15, wherein the back metal contact is deposited by plasma enhanced chemical vapor deposition.

18. The method of claim 15, wherein the back metal contact is deposited by sputtering.

19. The method of claim 15, wherein the poly-silicon back metal contact is a p-type doped poly-silicon.

20. A method of manufacturing a photovoltaic device comprising:
depositing a first semiconductor layer, the first semiconductor layer including a cadmium sulfide semiconductor;
depositing a second semiconductor layer on the first semiconductor layer, the second semiconductor layer including a cadmium telluride semiconductor; and
depositing a back metal contact, the back metal contact including an amorphous-silicon.

21. The method of claim 20, wherein the back metal contact is deposited by low pressure chemical vapor deposition.

22. The method of claim 20, wherein the back metal contact is deposited by plasma enhanced chemical vapor deposition.

23. The method of claim 20, wherein the back metal contact is deposited by sputtering.

24. The method of claim 20, wherein the amorphous-silicon back metal contact includes a boron dopant.
